(19) United States
(12) Patent Application Publication
(10) Pub. No.: US 2026/0089859 A1
(43) Pub. Date: Mar. 26, 2026

(54) SIDE-MOUNTED PERFORATED HANDLE ASSEMBLIES FOR INCREASING INLET AIRFLOW IN SERVER CHASSIS

(71) Applicant: Aivres Systems Inc., Fremont, CA (US)

(72) Inventor: Yuan-Bo LAN, Taipei (TW)

(21) Appl. No.: 19/404,740

(22) Filed: Dec. 1, 2025

(51) Int. Cl. H05K 5/02

(52) U.S. Cl. CPC H05K 5/023; H05K 5/0213

(57) ABSTRACT

An enclosure for standalone computing devices integrates a pair of side intake handle assemblies to increase cooling airflow while providing lift capability. Each assembly mounts to an opposing sidewall upstream of internal fans and includes a multi-surface intake housing with exterior air-admitting surfaces (e.g., perforations, slots, louvers, mesh) that communicate through a sidewall opening with an interior intake region. Solid edge rims and a partially non-perforated handle-mount area provide structural strength for lifting. In preferred layouts, the assemblies are located in lower sidewall regions aligned with a fan line to create a more direct intake path and reduce required fan speed for a given thermal load.

### TECHNICAL FIELD

The disclosure relates to thermal management and mechanical design of rack-mountable information-technology equipment, particularly server, storage, and accelerator enclosures that employ front-to-rear airflow. It addresses enclosure structures that simultaneously provide lifting ergonomics and additional inlet area to improve cooling performance under high power density.

### BACKGROUND

Contemporary device enclosures commonly rely on a plurality of fans to draw air through a perforated or meshed front panel and exhaust it toward a rear panel. Front panels and rack doors must balance inlet open area with structural stiffness and electromagnetic shielding, which constrains available intake at the front face.

As the number and power of heat-dissipating components within a chassis increase, solely relying on perforated or meshed front and rear panels can fail to provide sufficient air inflow along the airflow direction from the front panel toward the rear panel, which will lead to adding liquid cooling solutions. Cosmetic bezels, drive carriers, cabling, dust filters, and front doors add resistance, so even “high-open-area” panels may not deliver adequate mass flow to downstream heat sinks.

Increasing fan speed or adding to the plurality of fans raises noise and power consumption and yields diminishing returns when intake area is the bottleneck. Conventional handles are positioned for lifting only and do not contribute to intake. Accordingly, there is a need for a device enclosure architecture that increases available inlet open area upstream of the plurality of fans while maintaining electromagnetic shielding and mechanical strength, and that achieves this without sacrificing the lifting function provided by a handle.

### SUMMARY

The described structures improve thermal intake capacity and lifting strength for high-density, high-power hardware systems. The summary is intended to introduce certain innovative aspects in broad terms, and is not intended to limit the scope of any claim.

In one general aspect, a device enclosure may include a chassis having opposing sidewalls, a front panel, a rear panel, and a plurality of fans within the chassis, where each of the sidewalls has an opening. The device enclosure may also include a pair of side intake handle assemblies respectively mounted to the opposing sidewalls at locations upstream of the plurality of fans along an airflow direction from the front panel to the rear panel. Each side intake handle assembly may include a multi-surface intake housing that overlies the opening on the corresponding sidewall of the chassis and is configured to admit air into an interior space of the chassis through air-admitting features of the multi-surface intake housing and the opening on the sidewall, and a handle on the multi-surface intake housing configured to lift the device enclosure. Other embodiments of this aspect may include corresponding systems, apparatuses, and computer programs recorded on one or more computer storage devices, each configured to perform actions of the methods.

Implementations may include one or more of the following features. In some implementations, the multi-surface intake housing may include a pair of side surfaces, an upper surface, and a lower surface to admit air from two or more non-coplanar directions. In some implementations, edge regions at intersections between adjacent air-admitting surfaces of the multi-surface intake housing may be non-perforated structural members configured to transfer lifting loads from the handle to the chassis, where the non-perforated structural members form a continuous perimeter rim of the multi-surface intake housing. In some implementations, the multi-surface intake housing may include an outward-facing surface that is partially non-perforated to secure the handle and provide lifting strength. In some implementations, the multi-surface intake housing may include a plurality of air-admitting surfaces with a thickness of at least 2 mm.

In some implementations, the plurality of fans may be disposed in a lower portion of the chassis, and the pair of side intake handle assemblies may be mounted to corresponding lower portions of the opposing sidewalls aligned with the plurality of fans so as to provide a direct intake path from the pair of side intake handle assemblies to the plurality of fans. In some implementations, the multi-surface intake housing may include spatially graded air-admitting features that bias admitted flow toward a compartment housing graphics processing units (GPUs), accelerators, or chips. In some implementations, a lower surface of the multi-surface intake housing may be spaced above a base of the chassis by a clearance of about 10 mm to admit underflow through the lower surface of the multi-surface intake housing.

In some implementations, the multi-surface intake housing may be affixed to the chassis by welding or brazing along mating flanges. In some implementations, the handle may be removably attachable to the multi-surface intake housing while the multi-surface intake housing remains affixed to the chassis. In some implementations, the multi-surface intake housing may include air-admitting features selected from the group consisting of perforations, slots, louvers, mesh, and grids. In some implementations, operation of the plurality of fans may be controlled based on a temperature of a heat-dissipating component and, for a same thermal load, a fan rotational speed of the plurality of fans may be reduced relative to another device enclosure lacking the pair of side intake handle assemblies. In some implementations, the multi-surface intake housing may have a rectangular box geometry. In some implementations, the multi-surface intake housing may include a plurality of slanted side surfaces with perforations to reduce external projection. In some implementations, materials of the multi-surface intake housing may include steel, aluminum, or a conductive polymer composite. In some implementations, the pair of side intake handle assemblies may collectively increase an available inlet open area of the device enclosure by at least about fifteen percent relative to a device enclosure without the pair of side intake handle assemblies. Implementations of the described techniques may include hardware, a method or process, or a computer-readable medium.

In one general aspect, a side intake handle assembly may include a multi-surface intake housing having air-admitting features configured to communicate with an interior space of the chassis through an opening on a sidewall of the chassis when the side intake handle assembly is mounted to the chassis. The side intake handle assembly may also include a handle carried by the multi-surface intake housing and configured to lift the chassis. The multi-surface intake housing may include a plurality of air-admitting surfaces to admit air and may be configured to be mounted to the sidewall of the chassis at a location upstream of a plurality of fans inside the chassis along an airflow direction extending from a front panel toward a rear panel of the chassis. Other embodiments of this aspect may include corresponding systems, apparatuses, and computer programs recorded on one or more computer storage devices, each configured to perform actions of the methods.

Implementations may include one or more of the following features. In some implementations, edge regions at intersections between adjacent air-admitting surfaces may be non-perforated structural members configured to transfer lifting loads from the handle into the chassis, with the non-perforated structural members forming a continuous perimeter rim of the multi-surface intake housing. In some implementations, the plurality of air-admitting surfaces may include at least a pair of side surfaces, an upper surface, and a lower surface to admit air from two or more non-coplanar directions. In some implementations, where the plurality of fans are disposed in a lower portion of the chassis, the multi-surface intake housing may be configured to be mounted to corresponding lower portions of the sidewall aligned with the plurality of fans so as to provide a direct intake path from the multi-surface intake housing to the plurality of fans. Implementations of the described techniques may include hardware, a method or process, or a computer-readable medium.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 illustrates a front view of an example server chassis.

FIG. 2 illustrates a perspective view of an example server chassis with side intake handle assemblies, in accordance with some embodiments.

FIG. 3 illustrates a front view of the example server chassis with side intake handle assemblies, in accordance with some embodiments.

FIG. 4 illustrates a perspective view of the side intake handle assembly, in accordance with some embodiments.

FIG. 5 illustrates a front view of the side intake handle assembly, in accordance with some embodiments.

FIG. 6 illustrates a side view of the side intake handle assembly, in accordance with some embodiments.

FIG. 7 illustrates example geometries of the side intake handle assembly, in accordance with some embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

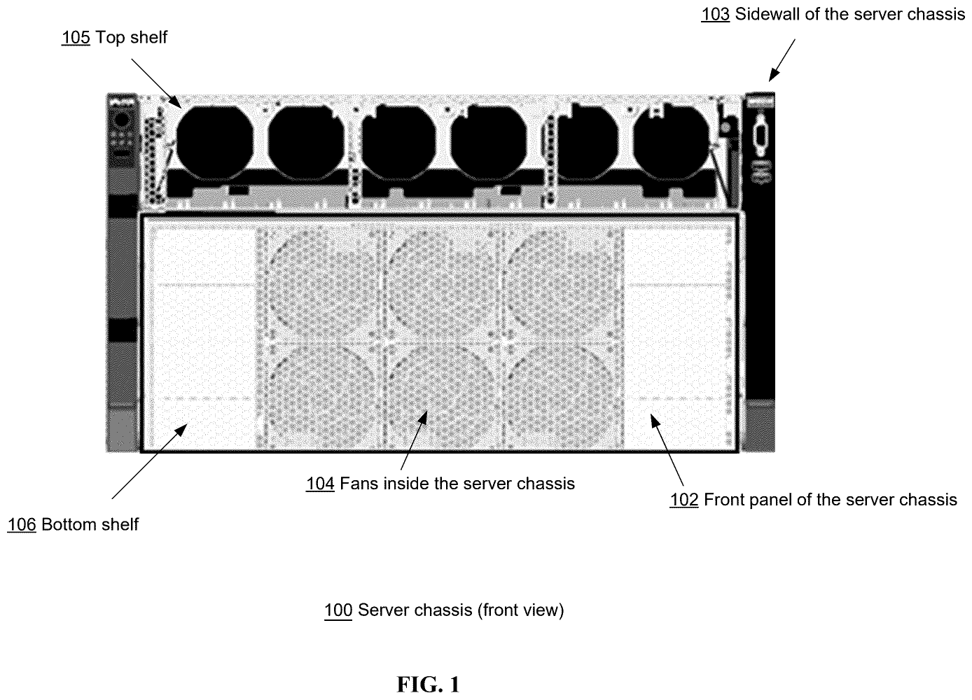

FIG. 1 illustrates a front view of an example server chassis 100 (a type of device enclosure). The server chassis 100 includes a front panel 102 and opposing sidewalls 103. As shown, the server chassis 100 is vertically partitioned into a top shelf 105 and a bottom shelf 106, each configured to host different heat-dissipating components. In the example of FIG. 1, a plurality of fans 104 are shown in a lower region (bottom shelf 106) of the server chassis and, in operation, draw air from the front panel 102 toward a rear panel (not shown in FIG. 1) along the airflow direction. As an example, the top shelf 105 may carry storage devices (HDDs/SSDs), memory, and one or more CPUs, while the bottom shelf 106 may carry graphics processing units (GPUs) or other accelerator cards.

As component power and density increase, the number of heat-generating devices hosted by the server chassis 100 may rise, while the server chassis 100 can support only a limited number of fans 104 with practical maximum rotational speeds. Even where the front panel 102 provides a high-open-area pattern, it has been observed in the industry that the effective intake at the front panel 102 may be insufficient to deliver the mass flow needed to cool downstream components on the shelves 105, 106.

To address these limitations, the following description introduces a pair of side intake handle assemblies configured to supplement the intake provided by the front panel 102. In some embodiments, each side intake handle assembly includes a multi-surface intake housing and a handle. Each side intake handle assembly may be mounted to a sidewall 103 of the server chassis 100 at a location upstream of the plurality of fans 104 in the direction of the airflow (e.g., from the front panel 102 to the rear panel). The structural features of the side intake handle assemblies are agnostic to the internal layout (for example, whether the chassis is divided into shelves or which components occupy them). The placement of the side intake handle assemblies, however, may be chosen with respect to the locations of the plurality of fans 104 so that admitted air couples efficiently into the interior space drawn by the fans along the airflow direction.

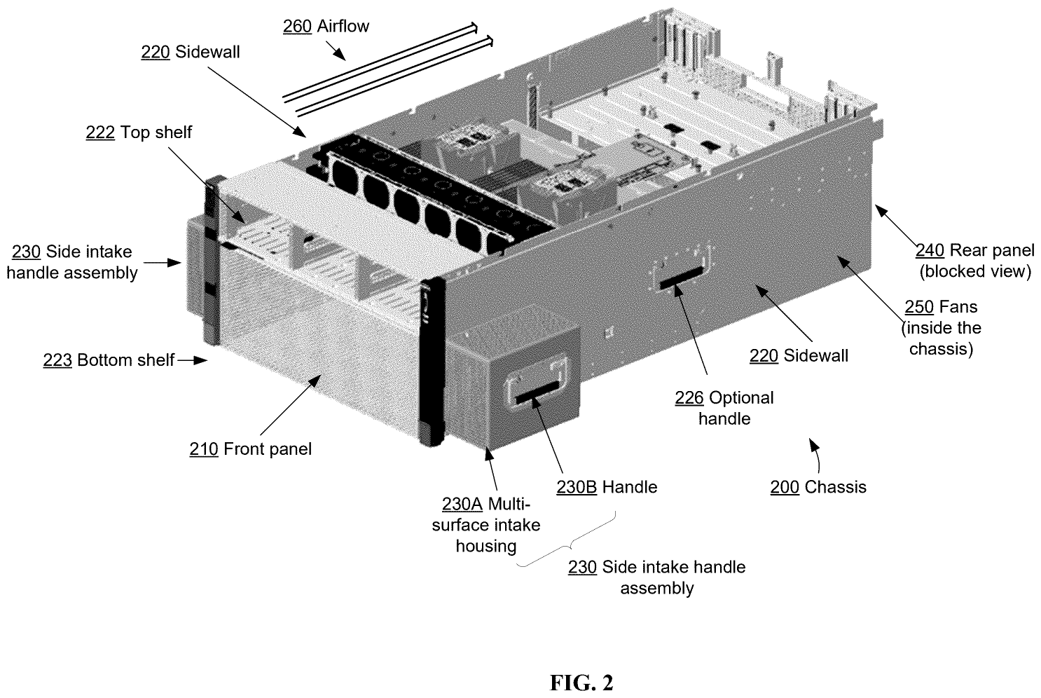

FIG. 2 illustrates a perspective view of an example device enclosure with side intake handle assemblies 230, in accordance with some embodiments. As in FIG. 1, a server chassis 200 is shown as an example of the device enclosure; however, the features described below are not limited to server chassis implementations.

As shown, the server chassis 200 includes a first panel (e.g., a front panel 210), opposing sidewalls 220, and a second panel (e.g., a rear panel 240, which is blocked from view in FIG. 2). Inside the server chassis 200, a plurality of fans 250 are arranged to draw air along an airflow direction 260 from the front panel 210 toward the rear panel 240. In some embodiments, the server chassis 200 is vertically partitioned into a top shelf 222 and a bottom shelf 223 configured to host different heat-dissipating components. For example, the top shelf 222 may host storage devices, memory, and one or more CPUs, and the bottom shelf 223 may host graphics processing units (GPUs), accelerators, or other chips. In the example of FIG. 2, the plurality of fans 250 reside in the bottom shelf 223 and generate the airflow direction 260 toward the rear panel 240.

In some embodiments, a pair of side intake handle assemblies 230 may be configured to be respectively mounted to the opposing sidewalls 220 at locations upstream of the plurality of fans 250 along the airflow direction 260. Each side intake handle assembly 230 includes a multi-surface intake housing 230A that overlies an opening on the corresponding sidewall 220 (also called sidewall opening) and is configured to admit air into an interior space of the chassis 200 through the sidewall opening, and a handle 230B on the multi-surface intake housing 230A configured to lift the chassis 200. In some embodiments, the multi-surface intake housing 230A has a plurality of air-admitting surfaces.

Placement of the side intake handle assemblies 230 upstream of the plurality of fans 250 is advantageous because air admitted by the multi-surface intake housing 230A is ingested by the plurality of fans 250 rather than being introduced downstream of the suction region, thereby increasing useful mass flow through internal heat sinks. In embodiments where the chassis 200 is vertically divided as shown and the plurality of fans 250 are located in the bottom shelf 223 to cool components on the bottom shelf 223, the side intake handle assemblies 230 may be mounted to lower portions of the opposing sidewalls 220 aligned with the plurality of fans 250, providing a direct intake path from the side intake handle assemblies 230 to the plurality of fans 250 along the airflow direction 260.

FIG. 2 shows an optional handle 226 on the sidewall 220, which represents a lifting location used when handles are provided for ergonomics. In some embodiments, the handle 230B on the multi-surface intake housing 230A is positioned closer to the front panel 210 than the handle 226 so that the handle 230B provides lifting while the multi-surface intake housing 230A simultaneously supplements intake area near the front panel 210. As more systems front-load weight due to components concentrated near the front panel 210, placing the handle 230B closer to the front panel 210 may improve lifting leverage and ergonomics during four-person carries. Although FIG. 2 depicts the handle 226, in some embodiments the handle 226 may be omitted entirely, with the pair of side intake handle assemblies 230 providing the lifting function.

In some embodiments, the multi-surface intake housing 230A may include air-admitting features selected from perforations, slots, louvers, mesh, or grids. In some embodiments, the air-admitting features on the multi-surface intake housing 230A are spatially graded to bias admitted flow toward a compartment on the bottom shelf 223 that houses graphics processing units (GPUs), accelerators, or chips. The side intake handle assemblies 230 may be affixed to the chassis 200 by welding or brazing along mating flanges, while the handle 230B may be removably attachable to the multi-surface intake housing 230A to facilitate service.

In some embodiments, operation of the plurality of fans 250 is controlled based on temperatures of heat-dissipating components, and, for the same thermal load, a fan rotational speed of the plurality of fans 250 may be reduced relative to a device enclosure lacking the side intake handle assemblies 230 due to increased available inlet open area provided by the side intake handle assemblies 230. In certain layouts, the pair of side intake handle assemblies 230 collectively increase the available inlet open area of the device enclosure by at least about fifteen percent relative to a device enclosure without the pair of side intake handle assemblies 230.

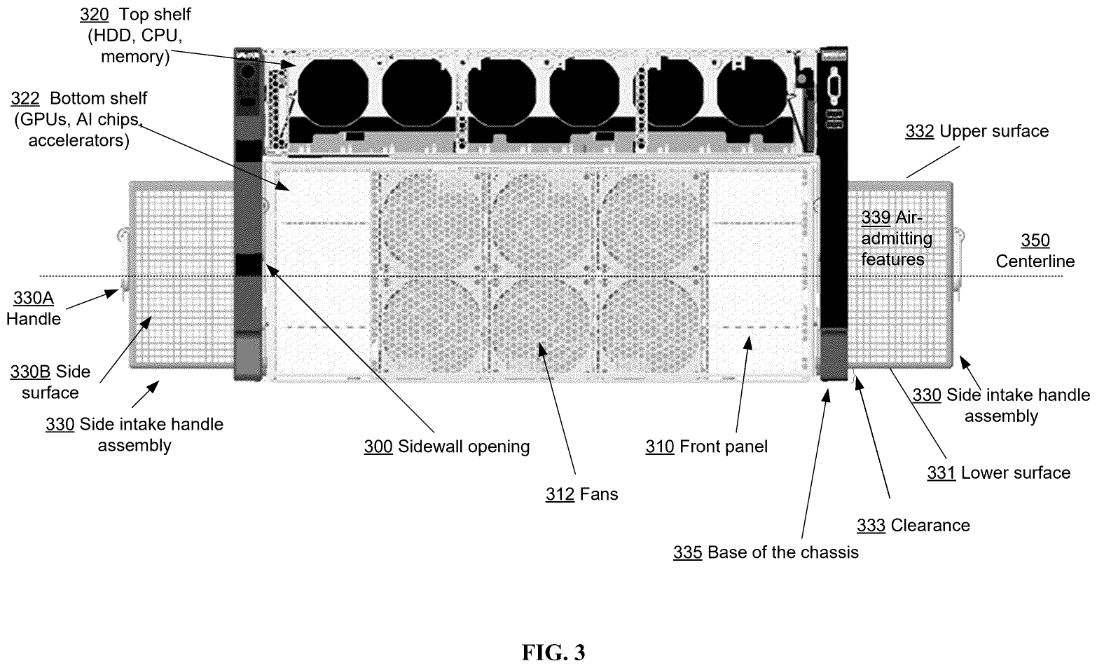

FIG. 3 illustrates a front view of an example device enclosure with a pair of side intake handle assemblies 330, in accordance with some embodiments. As shown, a front panel 310 spans the face of the chassis, and a plurality of fans 312 are disposed within the chassis in a lower region. In the embodiment shown, the chassis is vertically partitioned into a top shelf 320 and a bottom shelf 322.

In some embodiments, a pair of the side intake handle assemblies 330 are mounted to the sidewalls of the chassis. Each side intake handle assembly 330 includes a multi-surface intake housing having a rectangular box geometry and a handle 330A. The multi-surface intake housing overlies a sidewall opening 300 on the corresponding sidewall and communicates admitted air into the interior space of the chassis upstream of the plurality of fans 312. In some embodiments, the sidewall opening 300 is pre-formed in the corresponding sidewall and sized to match an inward opening (i.e., the internal mouth) of the multi-surface intake housing of the side intake handle assembly 330 so that the multi-surface intake housing overlies and seals the sidewall opening 300 when mounted. A local reinforcement bead or hem may be configured around the perimeter of the sidewall opening 300 to increase stiffness so that lifting loads transferred through the handle and through a perimeter rim of the multi-surface intake housing are reacted by the chassis without distorting the air-admitting surfaces. In some embodiments, the location of the sidewall opening 300 may be specified so that a centerline of the sidewall opening 300 is aligned with a centerline (both centerlines in FIG. 3 are aligned, both labeled as 350) of the plurality of fans 312, for example within a tolerance of a few millimeters, thereby preserving a direct intake path upstream of the plurality of fans along the airflow direction from the front panel toward the rear panel. Attachment of the multi-surface intake housing to the sidewall around the sidewall opening 300 may be accomplished by welding or brazing along the mating flanges, or by fasteners.

In some embodiments, the multi-surface intake housing presents side surfaces 330B (a pair, but only one is shown because of viewing angle), an upper surface 332, and a lower surface 331 so that air may enter from two or more (e.g., three or four) non-coplanar directions. In this disclosure, “non-coplanar directions” means approach directions for incoming air that are not all contained in a single geometric plane relative to the chassis, e.g., air admitted through the pair of side surfaces (respectively oriented toward the front panel and toward the rear panel), the upper surface, and the lower surface of the multi-surface intake housing, whose respective surface normals are mutually non-coplanar. “Non-coplanar” is also intended to include small angular deviations and manufacturing tolerances (for example, ±5-10 degrees). In some embodiments, the surfaces may include air-admitting features 339 implemented, for example, as grids, mesh, perforations, slots, or louvers. The air-admitting features may be distributed across the side surfaces 330B, the upper surface 332, and the lower surface 331 to increase effective exposure to the ambient and reduce approach losses.

As shown in FIG. 3, the pair of side intake handle assemblies 330 are mounted in lower portions of the opposing sidewalls and are laterally aligned with the plurality of fans 312. However, the “lower portion” is just an example, and the placement of the fans and the pair of side intake handle assemblies 330 may instead be disposed in corresponding vertical regions of the chassis and opposing sidewalls (e.g., the plurality of fans are disposed in a first vertical region of the chassis, and the pair of side intake handle assemblies are mounted to a second vertical region of the opposing sidewalls that are substantially vertically aligned with the first vertical region of the plurality of fans so as to provide a direct intake path from the pair of side intake handle assemblies to the plurality of fans). In some embodiments, a centerline of each multi-surface intake housing is aligned with a centerline of the fan assembly 312 to form a direct intake path from the side intake handle assemblies 330 into the suction regions of the plurality of fans 312. Locating the side intake handle assemblies 330 upstream of the plurality of fans 312 and at the same vertical band as the plurality of fans 312 shortens the intake path, reduces local pressure drop, and decreases recirculation at the lower corners of the front panel 310, thereby increasing the fraction of admitted flow that reaches heat-dissipating components in the bottom shelf 322.

In some embodiments, the lower surface 331 of each multi-surface intake housing is spaced above a base 335 of the chassis by a clearance 333. The clearance 333 may be about 10 mm (e.g., within a range of 8-15 mm) to admit underflow through the lower surface 331 while maintaining ground clearance during handling. This underflow supplements the intake from the side surfaces 330B and the upper surface 332 and can increase the available inlet open area in the lower region of the front face, which is typically the most constrained portion of the flow path. The clearance 333 may also reduce boundary-layer blockage at the base of the chassis, improving the uniformity of inflow to the plurality of fans 312.

In some embodiments, the rectangular box geometry of the multi-surface intake housing illustrated in FIG. 3 provides a plurality of air-admitting surfaces that are easy to manufacture while maintaining structural stiffness for the handle 330A. In some embodiments, the rectangular box geometry may define straight edge regions that are non-perforated (solid) to transfer lifting loads to the chassis and to maintain dimensional stability of the air-admitting features during lifting. At the same time, the air-admitting surfaces may provide an aggregate open area selected to increase the available inlet open area by at least about fifteen percent (e.g., between ten to twenty percent) relative to a device enclosure without the side intake handle assemblies 330.

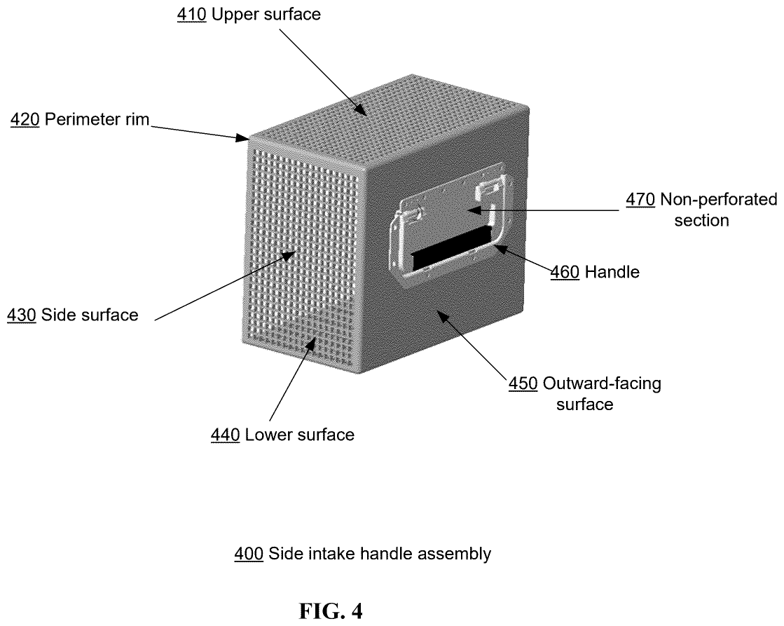

FIG. 4 illustrates a perspective view of a side intake handle assembly 400, in accordance with some embodiments. As described above, the side intake handle assembly 400 includes a multi-surface intake housing with a plurality of air-admitting surfaces, including an upper surface 410, a pair of side surfaces 430 (one is not visible from this perspective view. For clarity, the following description refers to the visible side surface 430, but the features are applicable to the other side surface as well), a lower surface 440, and an outward-facing surface 450. A handle 460 is mounted on the outward-facing surface 450. The multi-surface intake housing presents air-admitting features on at least the upper surface 410, the side surface 430, and the lower surface 440 so that ambient air may enter from non-coplanar directions and pass through a sidewall opening of the chassis.

In some embodiments, edge regions at the intersections of the air-admitting surfaces are formed as a continuous perimeter rim 420. In some embodiments, the perimeter rim 420 is non-perforated and acts as a structural member that ties the surfaces together into a closed rectangular frame. The perimeter rim 420 may be configured to transfer lifting loads from the handle 460 into mounting flanges on the multi-surface intake housing and then into the chassis sidewall. Providing a continuous perimeter rim 420 increases local bending stiffness and reduces stress concentration around the air-admitting features, which helps maintain geometric stability of the air-admitting features under lift and vibration.

In some embodiments, the outward-facing surface 450 may be partially non-perforated to secure the handle 460. In the example shown, a non-perforated section 470 surrounds the handle 460 and provides a solid attachment land for fasteners or welds. This non-perforated section 470 distributes pull-out and peel loads from the handle 460 into the perimeter rim 420 and adjacent panels, while the remainder of the outward-facing surface 450 may include perforations, slots, louvers, mesh, or grids to contribute to intake area. In some embodiments, when the device enclosure has a relatively high operating mass, the outward-facing surface 450 may be fully solid to maximize lifting strength and to minimize local deformation around the handle 460 while still allowing substantial intake through the upper surface 410, side surface 430, and lower surface 440.

In some embodiments, the air-admitting surfaces of the side intake handle assembly 400 may have a wall thickness of at least 2 mm. For example, a thickness in the range of about 2-3.5 mm may be selected to balance panel rigidity under lift with manufacturability of perforations and louvers. A thicker perimeter rim 420, such as about 3-4 mm, may be used in some embodiments.

Materials for the multi-surface intake housing may include steel, aluminum, or a conductive polymer composite. Aluminum alloys may reduce mass and ease forming of louvers. Steel may be preferred where maximum lift strength and dent resistance are required. Conductive polymer composites may be used to integrate complex lattice patterns with low weight while preserving shielding continuity. In each case, the material choice may be coordinated with the thickness noted above so that the handle 460 meets a target lift rating, for example four-person carry for assemblies exceeding 100 kg, with an appropriate safety factor.

From a thermal standpoint, distributing perforations over the upper surface 410, the pair of side surfaces 430, and lower surface 440 increases approach exposure and reduces entrance losses compared to a single-face intake. The non-perforated perimeter rim 420 and the non-perforated section 470 allow the intake area to be expanded without compromising structural requirements for lifting. This arrangement allows the side intake handle assembly 400 to function both as a high-porosity intake structure and as a robust lifting interface, supporting the claims regarding the perimeter rim, the partially or fully solid outward-facing surface, the minimum panel thickness, and the specified material systems.

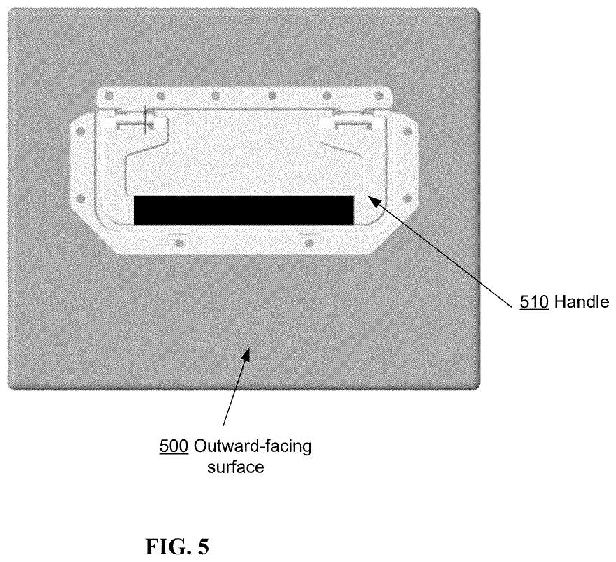

FIG. 5 illustrates a front view of a side intake handle assembly, in accordance with some embodiments. The outward-facing surface 500 of the multi-surface intake housing is shown as fully solid, and a handle 510 is mounted on the outward-facing surface 500.

In some embodiments, making the outward-facing surface 500 fully solid increases local stiffness and provides a robust land for attaching the handle 510, improving the transfer of lifting loads into the multi-surface intake housing and then into the chassis. A solid outward-facing surface 500 may also facilitate electromagnetic shielding continuity and provide sealing geometry around the handle 510.

Although FIG. 5 shows a fully solid outward-facing surface 500, other embodiments may implement a partially non-perforated region around the handle 510 with air-admitting features elsewhere on the outward-facing surface 500, while the upper and lower surfaces of the multi-surface intake housing continue to admit air from non-coplanar directions.

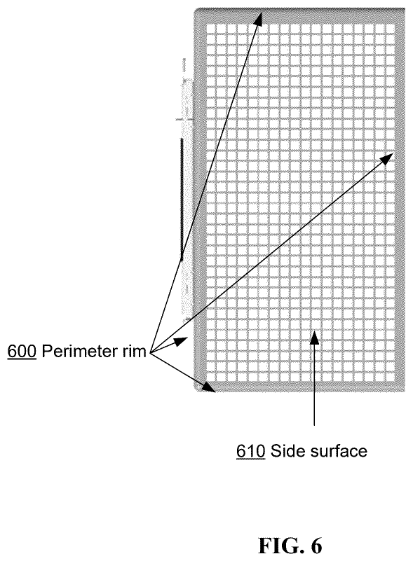

FIG. 6 illustrates a side view of a side intake handle assembly, in accordance with some embodiments. A side surface 610 of the multi-surface intake housing is shown with air-admitting features, and a continuous perimeter rim 600 surrounds the side surface 610.

In some embodiments, the perimeter rim 600 is a non-perforated structural member that runs along all edges of the side surface 610 and continues around adjacent surfaces of the multi-surface intake housing. The perimeter rim 600 may have increased wall thickness relative to the air-admitting portion of the side surface 610 so that lifting loads applied through the handle are transferred through the perimeter rim 600 into the chassis, thereby protecting the perforated regions from peak stress.

In some embodiments, the perimeter rim 600 may provide local stiffness for the multi-surface intake housing, reduce vibration of the air-admitting portion of the side surface 610 under fan suction, and define a flat land for welding or brazing to mating flanges of the chassis.

In some embodiments, the corner regions of the perimeter rim 600 may be radiused to distribute stress and to simplify manufacturing. In some embodiments, the perimeter rim 600 is formed from the same material and thickness specified for the multi-surface intake housing or from a locally thickened section to satisfy lifting requirements while maintaining airflow through the side surface 610.

Although FIG. 6 depicts the side surface 610, similar perimeter rims 600 may bound the upper surface and lower surface of the multi-surface intake housing so that the non-perforated structural members together form a continuous perimeter rim of the multi-surface intake housing.

In some embodiments, the side surface 610 of the multi-surface intake housing employs air-admitting features selected from perforations, slots, louvers, mesh, or grids. Perforations may be circular, hexagonal, or square and may be arranged on a staggered or orthogonal pitch. For example, a hexagonal pattern with a pitch of 3-6 mm and ligament widths of 0.5-1.0 mm can yield an open-area ratio of approximately 50-70% while maintaining sheet integrity. Slots may be oriented vertically to bias flow toward a lower portion of the chassis or horizontally to reduce flow noise. Louvers may be formed with a louver angle of about 15-35 degrees to impart directionality toward an interior intake space and to add incidental electromagnetic shielding.

In other embodiments, the side surface 610 is realized as a welded or fastened mesh or grid panel. A welded-wire grid with wire diameters of 1-2 mm and cell sizes of 8-15 mm can provide very high porosity with good dent resistance. An expanded-metal mesh may also be used to avoid burrs and to increase stiffness through strand work-hardening. When mesh or grid constructions are used, an edge margin of at least 5-10 mm may be left around the perimeter so that the perimeter rim 600 can carry lifting loads without stressing the mesh welds.

Spatial variation of the air-admitting features may be provided on the side surface 610 to implement graded openings. For example, the feature density can be increased toward the region aligned with fans inside the chassis or toward a compartment housing graphics processing units so that admitted flow is preferentially directed to high-load zones. The grading may be achieved by varying hole diameter, pitch, louver angle, or mesh wire diameter while keeping a constant outer boundary defined by the perimeter rim 600.

The selection among perforations, slots, louvers, mesh, and grids may be driven by tradeoffs among open area, structural stiffness, acoustic performance, and electromagnetic shielding. Perforated sheets can be laser-cut or punched from steel, aluminum, or conductive polymer composite and then formed with the perimeter rim 600 in a single operation; mesh and grid panels may be framed by the perimeter rim 600 and spot-welded or brazed to create a continuous mechanical load path and a low-impedance electrical path for shielding continuity.

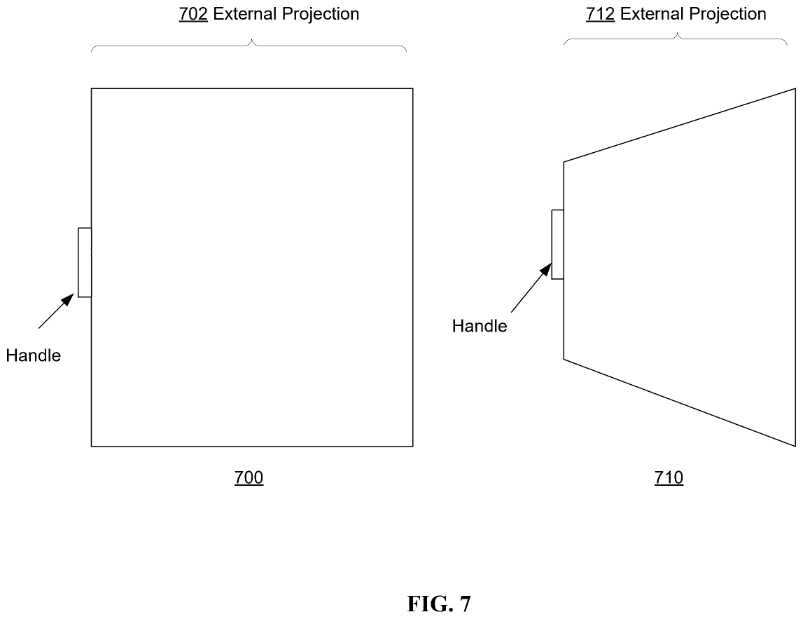

FIG. 7 illustrates two example geometries for the side intake handle assembly. On the left, view 700 depicts a side intake handle assembly in which the multi-surface intake housing has a rectangular box geometry with generally orthogonal surfaces and a substantially constant external projection 702. On the right, view 710 depicts a side intake handle assembly in which the multi-surface intake housing includes slanted side surfaces with perforations. In some embodiments, the slanted side surfaces taper toward the chassis so that the external projection 712 is reduced relative to the rectangular box geometry (712 is smaller than 702) while maintaining comparable or greater air-admitting area by distributing perforations over the slanted panels. The handle remains positioned on the outward-facing surface, and a perimeter rim may continue around all air-admitting surfaces to transfer lifting loads into the chassis. The slanted configuration may, for example, improve aisle and door clearances, mitigate snag risk, and lower acoustic wake, while the perforations on the slanted side surfaces may be spatially graded to direct admitted flow toward fans located downstream along the airflow direction.

In some embodiments, the side intake handle assembly may be manufactured and sold separately from the chassis. For factory builds, the side intake handle assembly may be welded or brazed to the sidewall of the chassis during fabrication. In other embodiments, the chassis may be shipped with a pre-formed sidewall region that is closed by a removable cover or scored knock-out sized as a “sidewall opening” for later installation. During field or depot installation, the cover may be removed (or the knock-out released) to expose the sidewall opening, and the multi-surface intake housing may be positioned to overlie and communicate with the interior space of the chassis through the sidewall opening.

The side intake handle assembly may be provided as a kit comprising the multi-surface intake housing and a handle carried by the multi-surface intake housing and configured to lift the chassis. The multi-surface intake housing may include a plurality of air-admitting surfaces (for example, a pair of side surfaces, an upper surface, and a lower surface) so that air is admitted from non-coplanar directions when the side intake handle assembly is mounted to the chassis. Edge regions at intersections between adjacent air-admitting surfaces may be non-perforated structural members forming a continuous perimeter rim that transfers lifting loads from the handle into the chassis after mounting.

In some embodiments, the chassis may include locator features adjacent the sidewall opening so that the multi-surface intake housing is mounted at a location upstream of a plurality of fans inside the chassis along an airflow direction extending from a front panel toward a rear panel of the chassis. Where the plurality of fans are disposed in a lower portion of the chassis, the multi-surface intake housing may be configured to be mounted to a corresponding lower portion of the sidewall aligned with the plurality of fans so as to provide a direct intake path from the multi-surface intake housing to the plurality of fans. Attachment may be accomplished by welding or brazing along mating flanges, or by fasteners.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. A device enclosure, comprising:
a chassis comprising opposing sidewalls, a first panel, a second panel, and a plurality of fans, each of the sidewalls comprising an opening; and
a pair of side intake handle assemblies respectively mounted to the opposing sidewalls at locations upstream of the plurality of fans along an airflow direction from the first panel to the second panel,
each side intake handle assembly comprising:
a multi-surface intake housing that overlies the opening on the corresponding sidewall of the chassis and is configured to admit air into an interior space of the chassis through the opening, and
a handle on the multi-surface intake housing and configured to facilitate lifting the device enclosure.

2. The device enclosure of claim 1, wherein the multi-surface intake housing comprises at least a pair of side surfaces, an upper surface, and a lower surface to admit air from two or more non-coplanar directions.

3. The device enclosure of claim 1, wherein edge regions at intersections between adjacent air-admitting surfaces of the multi-surface intake housing are non-perforated structural members configured to transfer lifting loads from the handle to the chassis,
wherein the non-perforated structural members form a continuous perimeter rim of the multi-surface intake housing.

4. The device enclosure of claim 1, wherein the multi-surface intake housing comprises an outward-facing surface that is partially non-perforated to secure the handle and provide lifting strength.

5. The device enclosure of claim 1, wherein the multi-surface intake housing comprises a plurality of air-admitting surfaces with a thickness of at least 2 mm.

6. The device enclosure of claim 1, wherein the plurality of fans are disposed in a first vertical region of the chassis, and the pair of side intake handle assemblies are mounted to a second vertical region of the opposing sidewalls that are substantially vertically aligned with the first vertical region of the plurality of fans so as to provide a direct intake path from the pair of side intake handle assemblies to the plurality of fans.

7. The device enclosure of claim 1, wherein the multi-surface intake housing comprises spatially graded air-admitting features that bias admitted flow toward a compartment housing graphics processing units (GPUs), accelerators, or chips.

8. The device enclosure of claim 1, wherein a lower surface of the multi-surface intake housing is spaced above a base of the chassis by a clearance to admit underflow through the lower surface of the multi-surface intake housing.

9. The device enclosure of claim 1, wherein the multi-surface intake housing is affixed to the chassis by welding or brazing along mating flanges.

10. The device enclosure of claim 9, wherein the handle is removably attachable to the multi-surface intake housing while the multi-surface intake housing remains affixed to the chassis.

11. The device enclosure of claim 1, wherein the multi-surface intake housing comprises air-admitting features selected from the group consisting of perforations, slots, louvers, mesh, and grids.

12. The device enclosure of claim 1, wherein operation of the plurality of fans is controlled based on a temperature of a heat-dissipating component, and,
for a same thermal load, a fan rotational speed of the plurality of fans is reduced relative to another device enclosure lacking the pair of side intake handle assemblies.

13. The device enclosure of claim 1, wherein the multi-surface intake housing has a rectangular box geometry.

14. The device enclosure of claim 1, wherein the multi-surface intake housing comprises a plurality of slanted side surfaces with perforations to reduce external projection.

15. The device enclosure of claim 1, wherein materials of the multi-surface intake housing comprise steel, aluminum, or a conductive polymer composite.

16. The device enclosure of claim 1, wherein the pair of side intake handle assemblies collectively increase an available inlet open area of the device enclosure by at least about fifteen percent relative to a device enclosure without the pair of side intake handle assemblies.

17. A side intake handle assembly for a chassis, comprising:
a multi-surface intake housing comprising air-admitting features configured to communicate with an interior space of the chassis through an opening on a sidewall of the chassis when the side intake handle assembly is mounted to the chassis; and
a handle carried by the multi-surface intake housing and configured to facilitate lifting the chassis,
wherein the multi-surface intake housing comprises a plurality of air-admitting surfaces to admit air, and
the multi-surface intake housing is configured to be mounted to the sidewall of the chassis at a location upstream of a plurality of fans inside the chassis along an airflow direction extending from a first panel toward a second panel of the chassis.

18. The side intake handle assembly of claim 17, wherein edge regions at intersections between adjacent air-admitting surfaces are non-perforated structural members configured to transfer lifting loads from the handle into the chassis, the non-perforated structural members forming a continuous perimeter rim of the multi-surface intake housing.

19. The side intake handle assembly of claim 17, wherein the plurality of air-admitting surfaces comprise at least a pair of side surfaces, an upper surface, and a lower surface to admit air from non-coplanar directions.

20. The side intake handle assembly of claim 17, wherein the plurality of fans are disposed in a first vertical region of the chassis, and the pair of side intake handle assemblies are mounted to a second vertical region of the opposing sidewalls that are substantially vertically aligned with the first vertical region of the plurality of fans so as to provide a direct intake path from the pair of side intake handle assemblies to the plurality of fans.
